(19) United States
(12) Patent Application Publication
(10) Pub. No.: US 2018/0294367 A1
(43) Pub. Date: Oct. 11, 2018

(54) BACK CONTACT SOLAR CELL SUBSTRATE, METHOD OF MANUFACTURING THE SAME AND BACK CONTACT SOLAR CELL

(71) Applicant: BYD COMPANY LIMITED, Shenzhen (CN)

(72) Inventors: XIANG SUN, SHENZHEN (CN); YUNJIANG YAO, SHENZHEN (CN)

(21) Appl. No.: 16/007,297

(22) Filed: Jun. 13, 2018

Related U.S. Application Data
(63) Continuation of application No. PCT/CN2016/111362, filed on Dec. 21, 2016.

(30) Foreign Application Priority Data
Dec. 23, 2015 (CN) 201510980464.8

(51) Int. Cl. H01L 31/0224; H01L 31/05

(52) U.S. Cl. CPC H01L 31/022441; H01L 31/0516

(57) ABSTRACT

A back contact solar cell substrate, a method of manufacturing the same and a back contact solar cell including the same are provided. The back contact solar cell substrate includes: a silicon chip, a light-receiving grid line disposed on a light-receiving surface of the silicon chip, a side connecting element disposed on a side surface of the silicon chip and insulated from the silicon chip; a positive electrode disposed on a backlight surface of the silicon chip; a negative electrode disposed on and insulated from the backlight surface of the silicon chip, and electrically connected to the light-receiving grid line through the side connecting element; and a back surface field disposed between the positive electrode and the backlight surface of the silicon chip, and electrically connected with the positive electrode.

### CROSS-REFERENCE TO RELATED APPLICATION

This application is a continuation application of International Patent Application No. PCT/CN2016/111362, filed on Dec. 21, 2016, which is based on and claims priority to Chinese Patent Application Serial No. 201510980464.8 filed on Dec. 23, 2015. All contents of the above-referenced applications are hereby incorporated by reference in their entity.

### FIELD

The present disclosure generally relates to a field of solar cell, especially relates to a back contact solar cell substrate, a method of manufacturing the same and a back contact solar cell.

### BACKGROUND

A traditional crystalline silicon solar cell includes two or three silver primary grid lines, which are configured as positive electrode and negative electrode, disposed on its front surface and back surface respectively. These primary grid lines may consume a large amount of silver. In addition, a photoelectric conversion efficiency may be reduced because sunlight is blocked by these primary grid lines. Moreover, as the positive electrode and the negative electrode are disposed on the front surface and the back surface respectively, when connecting cells in series, the electrode on the front surface of a cell should be welded to the electrode on the back surface of an adjacent cell through a weld strip, the welding process is complicated, and consumption of solder material is large, and a solar cell substrate may be broken during the welding or subsequent laminating process.

Regarding the problem of light shading loss on the front surface of the solar cell, an EWT (emitter wrap through) back contact solar cell, a MWT (metal wrap through) back contact solar cell and an IBC (interdigitated back contact) solar cell are provided. There are no grid lines (for example, EWT back contact solar cell, IBC solar cell) or no primary grid lines (for example, MWT back contact solar cell) on the front surfaces of these back contact solar cells, a shading area may be reduced, thus improving a power of the solar cell.

However, a manufacturing process of these solar cells (EWT, MWT and IBC) is very complicated. For example, for a MWT back contact solar cell and an EWT back contact solar cell, there is a need to laser punch on a silicon chip and the electrode or emitter region needs to be prepared to the back surface of the solar cell, which are difficult and expensive. While for an IBC solar cell, requirement of manufacturing process is extremely high.

Moreover, in the currently new technology, the solar cell substrates are arranged in a tile type to form a solar cell assembly, therefore, the solar cell substrate is easily broken and damaged during the welding or subsequent laminating process, and solar cell substrate on a stacking position cannot participate in power generation, which may cause waste and affect the power of the solar cell assembly.

### SUMMARY

The present disclosure seeks to solve at least one of the technical problems in the related art to some extent. Therefore, embodiments of the present disclosure provide a back contact solar cell substrate and a method for manufacturing the same, and a back contact solar cell. The back contact solar cell substrate according to the disclosure may be produced simply with the method, and the light-receiving area of the back contact solar cell substrate is large, also the generation power of cell is improved while the material forming the same is saved.

According a first aspect of embodiments of the present disclosure, a back contact solar cell substrate is provided. The back contact solar cell substrate includes: a silicon chip, a light-receiving grid line disposed on a light-receiving surface of the silicon chip, a side connecting element disposed on a side surface of the silicon chip and insulated from the silicon chip; a positive electrode disposed on a backlight surface of the silicon chip; a negative electrode disposed on and insulated from the backlight surface of the silicon chip, and electrically connected to the light-receiving grid line through the side connecting element; and a back surface field disposed between the positive electrode and the backlight surface of the silicon chip, and electrically connected with the positive electrode.

According to a second aspect of embodiments of the present disclosure, a back contact solar cell substrate is provided. The back contact solar cell substrate includes: a silicon chip, a light-receiving grid line disposed on a light-receiving surface of the silicon chip, a side connecting element disposed on a side surface of the silicon chip and insulated from the silicon chip; a back surface field disposed on a backlight surface of the silicon chip; a positive electrode disposed on a surface of the back surface field and electrically connected with the back surface field; and a negative electrode disposed on the surface of the back surface field and insulated from the back surface field, and electrically connected to the light-receiving grid line through the side connecting element.

In some embodiments, the positive electrode and the negative electrode are disposed on two ends of the backlight surface of the silicon chip respectively.

In some embodiments, the back contact solar cell substrate includes a plurality of negative electrodes spaced apart from each other and electrically connected with each other via a conductive grid line, and the back contact solar cell substrate includes a plurality of positive electrodes spaced apart from each other.

In some embodiments, the side connecting element includes a conductive grid line, a conductive layer or a conductive plate.

In some embodiments, the back contact solar cell substrate includes one positive electrode and one negative electrode, and the positive electrode and the negative electrode are configured as strip-type and parallel to each other. In some embodiments, the one positive electrode and the one negative electrode are disposed on two ends of the backlight surface of the silicon chip respectively.

In some embodiments, the negative electrode is insulated from the backlight surface of the silicon chip via a back insulating element disposed between the negative electrode and the backlight surface of the silicon chip.

In some embodiments, the back insulating element is jointed to the back surface field thereby to cover the backlight surface of the silicon chip jointly.

In some embodiments, a first insulating element is disposed on an edge of the silicon chip, and the side connecting element is insulated from the side surface of the silicon chip and the backlight surface of the silicon chip via the first insulating element.

In some embodiments, a first insulating element is coated on an edge of the silicon chip, and the side connecting element is disposed on a surface of the first insulating element, and insulated from the side surface of the silicon chip and the backlight surface of the silicon chip via the first insulating element.

In some embodiments, the first insulating element is made of paraffin and/or polyester film.

In some embodiments, the silicon chip has a shape of rectangle, a length of 20 centimeters to 60 centimeters, and a width of 20 centimeters to 60 centimeters.

According to a third aspect of the present disclosure, a method of manufacturing a back contact solar cell substrate is provided. The method includes steps of: producing a light-receiving grid line by adhering material configured to form the light-receiving grid line on a light-receiving surface of a silicon chip; producing a back surface field by adhering material configured to form the back surface field on a backlight surface of the silicon chip; producing a positive electrode by adhering a positive electrode paste on a surface of the back surface field, and making the positive electrode be electrically connected with the back surface field; producing a negative electrode by adhering a negative electrode paste on the backlight surface of the silicon chip, and making the negative electrode be insulated from the backlight surface of the silicon chip; and providing a side connecting element on a side surface of the silicon chip, insulating the side connecting element from the side surface of the silicon chip, and electrically connecting the side connecting element between the negative electrode and the light-receiving grid line.

According to a fourth aspect of the present disclosure, a method of manufacturing a back contact solar cell substrate is provided. The method includes steps of: producing a light-receiving grid line by adhering material configured to form the light-receiving grid line on a light-receiving surface of a silicon chip; producing a back surface field by adhering material configured to form the back surface field on a backlight surface of the silicon chip; producing a positive electrode by adhering a positive electrode paste on a surface of the back surface field, and making the positive electrode be electrically connected with the back surface field; producing a negative electrode by adhering a negative electrode paste on the surface of the back surface field, and making the negative electrode be insulated from the surface of the back surface field; and providing a side connecting element on a side surface of the silicon chip, insulating the side connecting element from the side surface of the silicon chip, and electrically connecting the side connecting element between the negative electrode and the light-receiving grid line.

In some embodiments, the positive electrode and the negative electrode are provided on two ends of the backlight surface of the silicon chip respectively.

In some embodiments, a plurality of negative electrodes spaced apart from each other and electrically connected with each other via a conductive grid line are provided, and a plurality of positive electrodes spaced apart from each other are provided.

In some embodiments, the side connecting element includes a conductive grid line, a conductive layer or a conductive plate.

In some embodiments, one positive electrode and one negative electrode are provided, and the positive electrode and the negative electrode are configured as strip-type and parallel to each other.

In some embodiments, the negative electrode is insulated from the backlight surface of the silicon chip via a back insulating element disposed between the negative electrode and the backlight surface of the silicon chip.

In some embodiments, the negative electrode is insulated from the back surface field via a back insulating element disposed between the negative electrode and the back surface field.

In some embodiments, the back insulating element is jointed to the back surface field thereby to cover the backlight surface of the silicon chip jointly.

In some embodiments, the side connecting element is insulated from the side surface of the silicon chip and the backlight surface of the silicon chip via a first insulating element, and the first insulating element is made of paraffin and/or polyester film.

In some embodiments, the silicon chip has a shape of rectangle, a length of 20 centimeters to 60 centimeters, and a width of 20 centimeters to 60 centimeters.

According to a fifth aspect of the present disclosure, a back contact solar cell is provided, the back contact solar cell includes: an upper cover plate, a first ethylene-vinyl acetate copolymer (EVA) adhesive layer, a plurality of back contact solar cell substrates mentioned above, a second ethylene-vinyl acetate copolymer (EVA) adhesive layer, and a back plate, two adjacent back contact solar cell substrates are connected in series or parallel.

The method of the present disclosure may simply a manufacturing process of a back contact solar cell and reduce cost. There is no primary grid line, which may block sun light, on front surface of the back contact solar cell substrate. That may improve a power of the solar cell. Both the positive and negative electrodes are provided on back surface of the back contact solar cell substrate, a welding process thereof may be simple, a consumption of solder may be reduced, and a breakage probability of the back contact solar cell substrate during welding or subsequent laminating process may be greatly reduced.

### BRIEF DESCRIPTION OF THE DRAWINGS

These and other aspects and advantages of embodiments of the present disclosure will become apparent and more readily appreciated from the following descriptions made with reference to the accompanying drawings, in which:

FIG. 1 is a side view of a back contact solar cell substrate according to an embodiment of the present disclosure; and

FIG. 2 is a schematic view of back contact solar cell according to an embodiment of the present disclosure.

### REFERENCE NUMERALS

1. light-receiving grid line; 2. antireflection layer; 3. diffusion layer; 4. silicon substrate; 5. back surface field; 6. positive electrode; 7. back insulating element; 8. negative electrode; 9. first insulating element; 10. side connecting element; 11. welding strip.

### DETAILED DESCRIPTION

Embodiments of the present disclosure are described in detail below, and examples of the embodiments are shown in accompanying drawings. The following embodiments described by referring to the accompanying drawings are illustrative, aim at explaining the present disclosure, and should not be interpreted as limitations to the present disclosure.

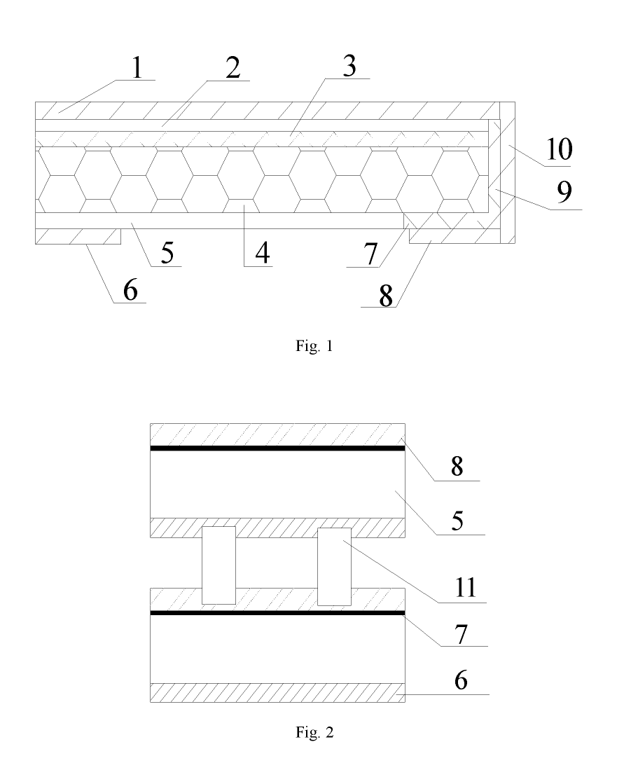

As shown in FIG. 1, a back contact solar cell substrate is provided. The back contact solar cell substrate includes a silicon, a light-receiving grid line 1 disposed on a light-receiving surface of the silicon chip, a side connecting element 10 disposed on a side surface of the silicon chip and insulated from the silicon chip; and a positive electrode 6 and a negative electrode 8 disposed on a backlight surface of the silicon chip. The negative electrode 8 is insulated from the backlight surface of the silicon chip, and the negative electrode 8 is electrically connected to the light-receiving grid line 1 through the side connecting element 10; and a back surface field 5 is disposed between the positive electrode 6 and the backlight surface of the silicon chip, and the positive electrode 6 is electrically connected with the back surface field 5.

In addition, the present disclosure also provides a back contact solar cell substrate. The back contact solar cell substrate includes a silicon chip, a light-receiving grid line 1 disposed on a light-receiving surface of the silicon chip, a side connecting element 10 disposed on a side surface of the silicon chip and insulated from the silicon chip, a back surface field 5 disposed on a backlight surface of the silicon chip, and a positive electrode 6 and a negative electrode 8 disposed on a surface of the back surface field 5. The negative electrode 8 is insulated from the back surface field 5, and electrically connected to the light-receiving grid line 1 through the side connecting element 10, the positive electrode 6 is electrically connected with the back surface field 5.

The silicon chip may be any commonly used silicon chip, such as, a silicon chip including a P-N junction, of which a light-receiving side is N-type semiconductor (phosphorus diffusion silicon), silicon substrate is P-type semiconductor (boron silicon), P-N junction is an interface between the N-type semiconductor and the P-type semiconductor.

In one specific embodiment, the silicon chip includes a silicon substrate 4, a diffusion layer 3 disposed on a light-receiving surface of the silicon substrate 4 and an antireflection layer 2 disposed on an upper surface of the diffusion layer 3. The light-receiving grid line 1 may be disposed on the antireflection layer 2. The antireflection layer 2 is configured to reduce a light reflection of the light-receiving surface of the solar cell and increase a quantity of light that passes through. A raw material for the antireflection layer 2 may be at least one selected from a group consisting of titanium dioxide, aluminum oxide, nitrogen doped silicon oxide and nitrogen doped silicon carbide. The diffusion layer 3 may include a phosphorus diffusion layer, and the silicon substrate 4 may include a boron doped silicon crystal silicon substrate.

In one embodiment, the positive electrode 6 and the negative electrode 8 are disposed on two ends of the backlight surface of the silicon chip respectively. Specifically, in one embodiment, the back contact solar cell substrate includes multiple negative electrodes 8 spaced apart from each other and electrically connected with each other via a conductive grid line, and the back contact solar cell substrate includes multiple positive electrodes 6 spaced apart from each other. In one embodiment, the back contact solar cell substrate includes one positive electrode 6 and one negative electrode 8, and the positive electrode 6 and the negative electrode 8 are configured as strip-type and parallel to each other, and the positive electrode 6 and the negative electrode 8 are disposed on two ends of the backlight surface of the silicon chip respectively.

The back surface field 5 may be a layer of aluminum film, and the back surface field 5 is configured to reduce a recombination probability of minority carrier on back surface of the silicon substrate 4.

The side connecting element 10 is configured to electrically connect the light-receiving grid line 1 and the negative electrode 8. In some embodiments, the side connecting element 10 includes a conductive grid line, a conductive layer or a conductive plate. It should be noted that when the side connecting element 10 includes a conductive grid line, the installation of the conductive grid line may realize an electric connection between the light-receiving grid line 1 and the negative electrode 8 disposed on the backlight surface of the silicon chip. In some embodiments, the conductive grid line and the light-receiving grid line are electrically connected with each other in a one-to-one correspondence, the negative electrode and the conductive grid line or an extension part of the conductive grid line are electrically connected on the backlight surface of the silicon chip, and the conductive grid line is insulated from the backlight surface and side surface of the silicon chip. A first insulating element 9 is disposed on a side of the silicon chip, or the first insulating element 9 is disposed on a side edge of the silicon chip and an edge of the backlight surface that is near to the side edge, as long as the conductive grid line, as the side connecting element 10, may be insulated from the backlight surface and side surface of the silicon chip, therefore the negative electrode that is connected to the conductive grid line is insulated from the backlight surface and side surface of the silicon chip, such that short circuit due to directly connection between the positive electrode and the negative electrode which are both disposed on the backlight surface of the silicon chip may be avoided.

When the side connecting element 10 includes a conductive layer or a conductive plate, the conductive layer or the conductive plate may not only cover the side edge of the silicon chip, but also the conductive layer or the conductive plate may coat the side surface of the silicon chip, so as to form a conductive layer on the light-receiving surface and the backlight surface near to the side edge. Then a better electric connection between the light-receiving grid line 1 and the side connecting element 10 may be realized. In addition, a better electric connection between the negative electrode disposed on the backlight surface of the silicon chip and the side connecting element 10 may be realized. Moreover, the side connecting element 10 is insulated from the backlight surface and the side surface of the silicon chip. Specifically, a first insulating element 9 is disposed on a side edge of the silicon chip, or the first insulating element 9 is disposed on a side edge of the silicon chip and an edge of the backlight surface that is near to the side edge, as long as the side connecting element may be insulated from the side surface of the silicon chip by means of the first insulating element 9, therefore the negative electrode connected to the side connecting element is insulated from the backlight surface and side surface of the silicon chip, which means that the first insulating element 9 ensures that the negative electrode electrically connected to the side connecting element is insulated from the side surface and the marginal part of the backlight surface of silicon chip, such that short circuit due to directly connection between the positive electrode and the negative electrode disposed on the backlight surface of the silicon chip may be avoided.

The negative electrode 8 is insulated from the backlight surface of the silicon chip. In one embodiment, the negative electrode 8 is insulated from the backlight surface of the silicon chip via a back insulating element 7 disposed between the negative electrode 8 and the backlight surface of the silicon chip.

The back insulating element 7 and the back surface field 5 may be located on a same plane, and the back insulating element 7 may also be disposed on surface of the back surface field 5. In one specific embodiment, the back insulating element 7 is jointed to the back surface field 5 thereby to cover the backlight surface of the silicon chip jointly.

A first insulating element 9 is disposed on an edge of the silicon chip, and the side connecting element 10 is insulated from the side surface of the silicon chip and the backlight surface of the silicon chip via the first insulating element 9. In one specific embodiment, a first insulating element 9 is coated on an edge of the silicon chip, and the side connecting element 10 is disposed on surface of the first insulating element 9 and insulated from the side surface of the silicon chip and the backlight surface of the silicon chip via the first insulating element 9. The edge of the silicon chip may include a side surface of the silicon chip and part area of the backlight surface of the silicon chip.

The back insulating element 7 and the first insulating element 9 may have a laminated shape, a plate shape, a grid shape or a strip shape, and a raw material of the back insulating element 7 and the first insulating element 9 may be acid and alkali resistant organic or inorganic material, such as, paraffin and/or polyester film.

The silicon chip may have a shape of rectangle, a length of about 20 centimeters to about 60 centimeters, and a width of about 20 centimeters to about 60 centimeters.

As shown in FIG. 1, the present disclosure further provides a method of manufacturing a back contact solar cell substrate. The method includes steps of: producing a light-receiving grid line 1 by adhering material configured to form the light-receiving grid line 1 on a light-receiving surface of a silicon chip; producing a back surface field 5 by adhering material configured to form the back surface field 5 on a backlight surface of the silicon chip; producing a positive electrode 6 by adhering a positive electrode paste on a surface of the back surface field 5, the positive electrode 6 being electrically connected with the back surface field 5; producing a negative electrode 8 by adhering a negative electrode paste on the backlight surface of the silicon chip, the negative electrode 8 being insulated from the backlight surface of the silicon chip; and providing a side connecting element 10 on a side surface of the silicon chip, insulating the side connecting element 10 from the side surface of the silicon chip, and electrically connecting the side connecting element 10 between the negative electrode 8 and the light-receiving grid line 1.

In addition, the present disclosure further provides a method of manufacturing a back contact solar cell substrate. The method includes steps of: producing a light-receiving grid line 1 by adhering material configured to form the light-receiving grid line 1 on a light-receiving surface of a silicon chip; producing a back surface field 5 by adhering material configured to form the back surface field 5 on a backlight surface of the silicon chip; producing a positive electrode 6 by adhering a positive electrode paste on a surface of the back surface field 5, the positive electrode 6 being electrically connected with the back surface field 5; producing a negative electrode 8 by adhering a negative electrode paste on the surface of the back surface field 5, the negative electrode 8 being insulated from the back surface field 5; and providing a side connecting element 10 on a side surface of the silicon chip, insulating the side connecting element 10 from the side surface of the silicon chip, and electrically connecting the side connecting element 10 between the negative electrode 8 and the light-receiving grid line 1.

The back surface field 5 may be a layer of aluminum film, and the back surface field is configured to reduce a recombination probability of minority carrier on back surface of the silicon substrate 4.

The method of adhering may be at least one of silk-screen printing, ink-jet printing and coating film.

The silicon chip may be any commonly used silicon chip, such as, a silicon chip including a P-N junction, of which a light-receiving side is N-type semiconductor (phosphorus diffusion silicon), backlight side is P-type semiconductor (boron silicon), P-N junction is an interface between the N-type semiconductor and the P-type semiconductor.

In one specific embodiment, the silicon chip includes a silicon substrate 4, a diffusion layer 3 disposed on a light-receiving surface of the silicon substrate 4 and an antireflection layer 2 disposed on an upper surface of the diffusion layer 3. The light-receiving grid line 1 may be disposed on a light-receiving surface of the antireflection layer 2. The antireflection layer 2 is configured to reduce a light reflection of the light-receiving surface of the solar cell and increase a quantity of light that passes through, while existence of the antireflection layer 2 won't affect the electric connection between the light-receiving grid line 1 and the diffusion layer 3. A raw material for the antireflection layer 2 may be at least one selected from a group consisting of titanium dioxide, aluminum oxide, nitrogen doped silicon oxide and nitrogen doped silicon carbide. The diffusion layer 3 may include a phosphorus diffusion layer, and the silicon substrate 4 may include a boron doped silicon crystal silicon substrate.

As shown in FIG. 1, the positive electrode 6 and the negative electrode 8 may be disposed on two ends of the backlight surface of the silicon chip respectively. Specifically, in one embodiment, multiple negative electrodes 8 spaced apart from each other and electrically connected with each other via a conductive grid line are provided, and multiple positive electrodes 6 spaced apart from each other are provided. In one embodiment, one positive electrode 6 and one negative electrode 8 are provided, and the positive electrode 6 and the negative electrode 8 are configured as a strip-type and parallel to each other, and the positive electrode 6 and the negative electrode 8 are disposed on two ends of the backlight surface of the silicon chip respectively.

The side connecting element is configured to electrically connect the light-receiving grid line 1 and the negative electrode 8. In some embodiments, the side connecting element 10 includes a conductive grid line, a conductive layer or a conductive plate.

The negative electrode 8 is insulated from the backlight surface of the silicon chip or insulated from the back surface field. In one embodiment, the negative electrode 8 is insulated from the backlight surface of the silicon chip via a back insulating element 7 disposed between the negative electrode 8 and the backlight surface of the silicon chip. In another embodiment, the negative electrode 8 is insulated from the back surface field 5 via a back insulating element 7 disposed between the negative electrode 8 and the back surface field 5.

The back insulating element 7 and the back surface field 5 may be located on a same plane, and the back insulating element 7 may also be disposed on surface of the back surface field 5. In one specific embodiment, the back insulating element 7 is jointed to the back surface field 5 thereby to cover the backlight surface of the silicon chip jointly.

A first insulating element 9 is disposed on an edge of the silicon chip, and the side connecting element 10 is insulated from the side surface of the silicon chip and the backlight surface of the silicon chip via the first insulating element 9. In one specific embodiment, the side connecting element 10 is insulated from the side surface of the silicon chip and the backlight surface of the silicon chip via the first insulating element 9. The back insulating element 7 and the first insulating element 9 may have a laminated shape, a plate shape, a grid shape or a strip shape, and a raw material of the back insulating element 7 and the first insulating element 9 may be acid and alkali resistant organic or inorganic material, such as, paraffin and/or polyester film. The edge of the silicon chip may include a side surface of the silicon chip and part area of the backlight surface of the silicon chip.

The silicon chip has a shape of rectangle, a length of about 20 centimeters to about 60 centimeters, and a width of about 20 centimeters to about 60 centimeters.

The present disclosure further provides a back contact solar cell, the back contact solar cell includes: an upper cover plate, a first ethylene-vinyl acetate copolymer adhesive layer, several back contact solar cell substrates mentioned above, a second ethylene-vinyl acetate copolymer adhesive layer, and a back plate, two adjacent back contact solar cell substrates are connected in series or parallel, for example the adjacent back contact solar cell substrates are connected in series or parallel via a welding strip.

In the specification, unless specified or limited otherwise, relative terms such as “above”, “below”, “up”, “top”, “bottom” as well as derivative thereof (e.g., “horizontally”, “downwardly”, “upwardly”, etc.) should be construed to refer to the orientation as then described or as shown in the drawings under discussion. These relative terms are for convenience of description and do not require that the present disclosure be constructed or operated in a particular orientation.

Reference will be made in detail to embodiments of the present disclosure. The embodiments described herein with reference to drawings are explanatory, illustrative, and used to generally understand the present disclosure. The embodiments shall not be construed to limit the present disclosure. In contrast, the present disclosure may include alternatives, modifications and equivalents within the spirit and scope of the appended claims.

It should be noted that, the particular features, structures, materials, or characteristics may be combined in any suitable manner in one or more embodiments or examples, which are not described herein for simplicity.

Although the embodiments of the present disclosure have been shown and described, those of ordinary skill in the art can understand that multiple changes, modifications, replacements, and variations may be made to these embodiments without departing from the principle and purpose of the present disclosure.

What is claimed is:

1. A back contact solar cell substrate, comprising:
a silicon chip,
a light-receiving grid line disposed on a light-receiving surface of the silicon chip,
a side connecting element disposed on a side surface of the silicon chip and insulated from the silicon chip;
a positive electrode disposed on a backlight surface of the silicon chip;
a back surface field disposed between the positive electrode and the backlight surface of the silicon chip, and electrically connected with the positive electrode; and
a negative electrode disposed on and insulated from the backlight surface of the silicon chip and electrically connected to the light-receiving grid line through the side connecting element.

2. The back contact solar cell substrate of claim 1, wherein the negative electrode is disposed on a surface of the back surface field on the backlight surface and insulated from the back surface field.

3. The back contact solar cell substrate of claim 1, wherein the back contact solar cell substrate comprises a plurality of negative electrodes spaced apart from each other and electrically connected with each other via a conductive grid line, and the back contact solar cell substrate comprises a plurality of positive electrodes spaced apart from each other.

4. The back contact solar cell substrate of claim 1, wherein the side connecting element comprises a conductive grid line, a conductive layer or a conductive plate.

5. The back contact solar cell substrate of claim 1, wherein the back contact solar cell substrate comprises one positive electrode and one negative electrode, and the positive electrode and the negative electrode are configured as strip-type and parallel to each other.

6. The back contact solar cell substrate of claim 1, wherein the negative electrode is insulated from the backlight surface of the silicon chip via a back insulating element disposed between the negative electrode and the backlight surface of the silicon chip.

7. The back contact solar cell substrate of claim 6, wherein the back insulating element is jointed to the back surface field.

8. The back contact solar cell substrate of claim 1, wherein a first insulating element is disposed on an edge of the silicon chip, and the side connecting element is insulated from the side surface of the silicon chip and the backlight surface of the silicon chip via the first insulating element.

9. The back contact solar cell substrate of claim 1, wherein a first insulating element is coated on an edge of the silicon chip, and the side connecting element is disposed on a surface of the first insulating element, and insulated from the side surface of the silicon chip and the backlight surface of the silicon chip via the first insulating element.

10. The back contact solar cell substrate of claim 9, wherein the first insulating element is made of paraffin and/or polyester film.

11. A method of manufacturing a back contact solar cell substrate, comprising:
producing a light-receiving grid line by adhering material configured to form the light-receiving grid line on a light-receiving surface of a silicon chip;
producing a back surface field by adhering material configured to form the back surface field on a backlight surface of the silicon chip;
producing a positive electrode by adhering a positive electrode paste on a surface of the back surface field, and making the positive electrode be electrically connected with the back surface field;
producing a negative electrode by adhering a negative electrode paste on the backlight surface of the silicon chip, and making the negative electrode be insulated from the backlight surface of the silicon chip; and
providing a side connecting element on a side surface of the silicon chip, insulating the side connecting element from the side surface of the silicon chip, and electrically connecting the side connecting element between the negative electrode and the light-receiving grid line.

12. The method of claim 11, wherein producing a negative electrode by adhering a negative electrode paste on the backlight surface of the silicon chip comprises adhering the negative electrode paste on the surface of the back surface field on the backlight surface of the silicon chip.

13. The method of claim 11, wherein one positive electrode and one negative electrode are provided, and the positive electrode and the negative electrode are configured as strip-type and parallel to each other.

14. The method of claim 11, wherein a plurality of negative electrodes spaced apart from each other and electrically connected with each other via a conductive grid line are provided, and a plurality of positive electrodes spaced apart from each other are provided.

15. The method of claim 11, wherein the side connecting element comprises a conductive grid line, a conductive layer or a conductive plate.

16. The method of claim 11, wherein the negative electrode is insulated from the backlight surface of the silicon chip via a back insulating element disposed between the negative electrode and the backlight surface of the silicon chip.

17. The method of claim 11, wherein the negative electrode is insulated from the back surface field via a back insulating element disposed between the negative electrode and the back surface field.

18. The method of claim 17, wherein the back insulating element is jointed to the back surface field.

19. The method of claim 11, wherein the side connecting element is insulated from the side surface of the silicon chip and the backlight surface of the silicon chip via a first insulating element, the first insulating element is made of paraffin and/or polyester film.

20. A back contact solar cell, comprising:
an upper cover plate,
a first ethylene-vinyl acetate copolymer adhesive layer,
a plurality of back contact solar cell substrates of claim 1,
a second ethylene-vinyl acetate copolymer adhesive layer, and
a back plate,
wherein two adjacent back contact solar cell substrates are connected in series or parallel.
